(19) United States
(12) Patent Application Publication
(10) Pub. No.: US 2005/0056968 A1
(43) Pub. Date: Mar. 17, 2005

(54) Forming homogeneous mixtures of organic materials for physical vapor deposition using wet mixing

(75) Inventors: Syamal K. Ghosh, Rochester, NY (US); Donn B. Carlton, Hamlin, NY (US); Tukaram K. Hatwar, Penfield, NY (US)

Correspondence Address: Thomas H. Close;Patent Legal Staff, Eastman Kodak Company, 343 State Street, Rochester, NY, 14650-2201, US

(73) Assignee: Eastman Kodak Company

(21) Appl. No.: 10/663,620

(22) Filed: Sep. 16, 2003

(51) Int. Cl. B06B 1/02; B29B 7/08; B29B 9/00

(52) U.S. Cl. 264/442; 264/118; 264/122; 264/349

(57) ABSTRACT

A method of forming a homogeneous mixture of powders of organic materials, which includes, at least one dopant component and one host component to form a pellet for thermal physical vapor deposition producing an organic layer on a substrate for use in an organic light-emitting device. The method includes, combining organic materials while an emulsifying liquid is provided, after which, the emulsified organic materials are mixed to form a homogeneous mixture of organic material. The homogenous mixture of organic materials is then heated in a container until the emulsifying liquid is evaporated and a solidified homogenous mixture of organic materials remains. The solidified homogeneous mixture of organic materials are removed from the container, pulverized into a homogeneous mixture of organic powder, and compacted to form pellets suitable for thermal physical vaporization to produce an organic layer on a substrate for use in an organic light-emitting device.

### CROSS REFERENCE TO RELATED APPLICATIONS

Reference is made to commonly assigned U.S. patent application Ser. No. 09/898,369 filed Jul. 3, 2001 entitled “Method of Handling Organic Material in Making An Organic Light-Emitting Device” by Van Slyke et al.; U.S. patent application Ser. No. 10/073,690 filed Feb. 11, 2002, entitled “Using Organic Materials in Making An Organic Light-Emitting Device” by Ghosh et al., U.S. patent application Ser. No. 10/195,947 filed Jul. 16, 2002, entitled “Compacting Moisture-Sensitive Organic Material in Making An Organic Light-Emitting Device” by Ghosh et al., U.S. patent application Ser. No. 10/226,600 filed Aug 23, 2002, entitled “Solid Compacted Pellet of Organic Material for Vacuum Deposition of OLED displays and Method of Making Same” by Ghosh et al., and U.S. patent application Ser. No. 10/348,118 filed Jan. 17, 2003, entitled “Using Compacted Organic Materials In Making White Light-emitting OLEDS” by Ghosh et al., U.S. patent application Ser. No. ______ filed concurrently herewith, entitled “Forming Homogeneous Mixtures of Organic Materials For Physical Vapor Deposition Using a Solvent” by Ghosh et al, U.S. patent application Ser. No. ______ filed concurrently herewith, entitled “Forming Homogeneous Mixtures of Organic Materials For Physical Vapor Deposition Using Melting” by Ghosh et al, and U.S. patent application Ser. No. ______ filed concurrently herewith, entitled “Forming Homogeneous Mixtures of Organic Materials For Physical Vapor Deposition Using Dry Mixing” by Ghosh et al, the teachings of which are incorporated herein.

### FIELD OF THE INVENTION

The present invention relates to forming homogeneous mixtures of two or more organic powder components for use in making an organic layer by physical vapor deposition on a substrate, which will form a part of an OLED display.

### BACKGROUND OF THE INVENTION

An organic light-emitting diode (OLED), also referred to as an organic electroluminescent device, can be constructed by sandwiching two or more organic layers between first and second electrodes.

Organic materials, thickness of vapor-deposited organic layers, and layer configurations, useful in constructing an organic light-emitting device are described for example, in commonly assigned U.S. Pat. Nos. 4,356,429; 4,539,507; 4,720,432; and 4,769,292, the disclosures of which are herein incorporated by reference.

Organic materials useful in making OLED displays, for example organic hole-transporting materials, organic light-emitting materials with an organic dopant, and organic electron-transporting materials can have relatively complex molecular structures with relatively weak molecular bonding forces, so care must be taken to avoid decomposition of the organic material during physical vapor deposition.

The aforementioned organic materials are synthesized to a relatively high degree of purity, and are provided in the form of powders, flakes, or granules. Such powders or flakes have been used heretofore for placement into a physical vapor deposition source wherein heat is applied for forming a vapor by sublimation or vaporization of the organic powder, the vapor condensing on a substrate to provide an organic layer thereon. In order to form a layer having more than one organic component, such as a host and a dopant component, it is desirable to co-evaporate simultaneously from two adjacent sources so that the organic components are mixed in the vapor-state prior to forming a layer on a substrate.

The co-evaporation process has several disadvantages which include (a) the vapor deposition chamber must be large to accommodate the evaporation sources for both the dopant and host component organic materials; (b) the large chambers necessary to complete co-evaporation are costly; (c) the larger the chamber, the more time that is required to reduce the pressure of the chamber prior to vaporization; and (d) each evaporation source containing a host or dopant component material must be vaporized by an independent power source, thereby increasing the cost of the co-evaporation process.

The rate of vaporization of each individual deposition source is crucial because that determines the chemical composition of the deposited organic layer on the substrate. In other words, the deposition rate determines the amount of vapor deposited on a substrate for a given length of time. Since the weight percentage of the dopant component in organic layers is lower than that of the host component, it is imperative that the deposition rate for the dopant component be adjusted accordingly. If the rate of vaporization of individual sources is not precisely controlled, the chemical composition of the vapor deposited on the substrate will be different from what is required to form a highly efficient OLED display.

Several problems associated with co-evaporation of organic powders, flakes or granules have also been discovered. Such problems include:
(i) powders, flakes, or granules are difficult to handle because they can acquire electrostatic charges via a process referred to as triboelectric charging;
(ii) powders, flakes, or granules of organic materials generally have a relatively low physical density (expressed in terms of weight per unit volume) in an approximate range from 0.05 to 0.2 g/cm³, compared to a physical density of an idealized solid organic material of approximately 1 g/cm³;
(iii) powders, flakes, or granules of organic materials have an undesirably low thermal conductivity, particularly when placed in a physical vapor deposition source which is disposed in a chamber evacuated to pressures as low as 10^{—6} Torr. Consequently, powder particles, flakes, or granules are heated only by radiative heating from a heated source, and by conductive heating of particles or flakes directly in contact with heated surfaces of the source. Powder particles, flakes, or granules which are not in contact with heated surfaces of the source are not effectively heated by conductive heating due to a relatively low particle-to-particle contact area; and
(iv) powders, flakes, or granules typically have a high ratio of surface area/volume and a correspondingly high propensity to entrap air and moisture between particles under ambient conditions. Consequently, a charge of organic powders, flakes, or granules loaded into a physical vapor deposition source, which is disposed in a chamber must be thoroughly outgased by preheating the source once the chamber has been evacuated to a reduced pressure.

If outgasing is omitted or is incomplete, particulate can be ejected from the evaporation source during the physical vapor deposition process. An OLED, having multiple organic layers, can become functionally inoperative if such layers include particles or particulates. Compaction of organic powders for making OLED displays using a physical vapor deposition method is described by Van Slyke et al. in a commonly assigned U.S. Patent Application Publication No. 2003/0008071 A1, the disclosure of which is incorporated herein by reference.

Each one, or a combination, of the aforementioned aspects of organic powders, flakes, or granules can lead to nonuniform heating of such organic materials in physical vapor deposition sources with attendant spatially nonuniform vaporization of organic material, which can, result in potentially nonuniform vapor-deposited organic layers formed on a structure.

### SUMMARY OF THE INVENTION

It is an object of the present invention to provide efficient methods of mixing organic materials adaptable for making on organic layer on a structure, which will form a part of an OLED display.

It is another object of the present invention to provide a homogeneous mixture of organic materials including at least one host and at least one dopant adaptable for making an organic layer on a structure, which will form a part of an OLED display.

In one aspect, the present invention provides a method of forming a homogeneous mixture of powders of organic materials including at least one dopant component and one host component to form a pellet for thermal physical vapor deposition producing an organic layer on a substrate for use in an organic light-emitting device.

These objects are achieved by
A method for forming homogeneous mixture of powders of organic materials including at least one dopant component and one host component to provide a homogeneous mixture for forming a pellet for thermal physical vapor deposition producing an organic layer on a substrate for use in an organic light-emitting device, comprising:
a) combining organic materials, such materials including at least one dopant component and one host component;
b) providing a liquid to emulsify the organic materials;
c) mixing the emulsified organic materials in a container to form a homogeneous mixture of organic material;
d) heating the organic materials in a container until the liquid is evaporated and a solidified homogeneous mixture of organic materials remain;
e) removing the solidified homogeneous mixture of organic materials from the container;
f) pulverizing the solidified mixture of organic materials into a homogeneous mixture of organic powder; and
g) compacting the homogenous mixture of organic powder, to form a pellet suitable for thermal physical vaporization to produce an organic layer on a substrate for use in an organic light-emitting device.

A feature of the present invention is an effective way to provide homogeneous mixtures of organic materials that can be vaporized from a single source thereby avoiding the problems associated with co-evaporation of single component materials.

Another beneficial feature of the present invention is that compacted pellets can be formed from homogenous mixtures of organic materials thereby avoiding the problems associated with vaporization of organic powders, flakes or granules.

Another beneficial feature of the present invention is that a compacted pellet formed from a homogeneous mixture of organic materials can be evaporated for a longer duration from a single evaporation source rather than co-evaporation from a multiple evaporation sources as in single component materials.

### BRIEF DESCRIPTION OF THE DRAWINGS

FIG. 1 depicts a schematic flowchart of using ball mill for mixing organic powders in dry or wet condition.

The term “powder” is used herein to denote a quantity of individual particles, which can be flakes, granules, or mixtures of varied particles and shapes comprising single or plurality of molecular species.

### DETAILED DESCRIPTION OF THE INVENTION

The organic layers of an OLED display include an organic or organo-metallic material that produces light, known as electroluminescence (EL), as a result of electron-hole recombination in the layer. Hereinafter, the term “organic” will be taken to include both purely organic as well as organo-metallic materials.

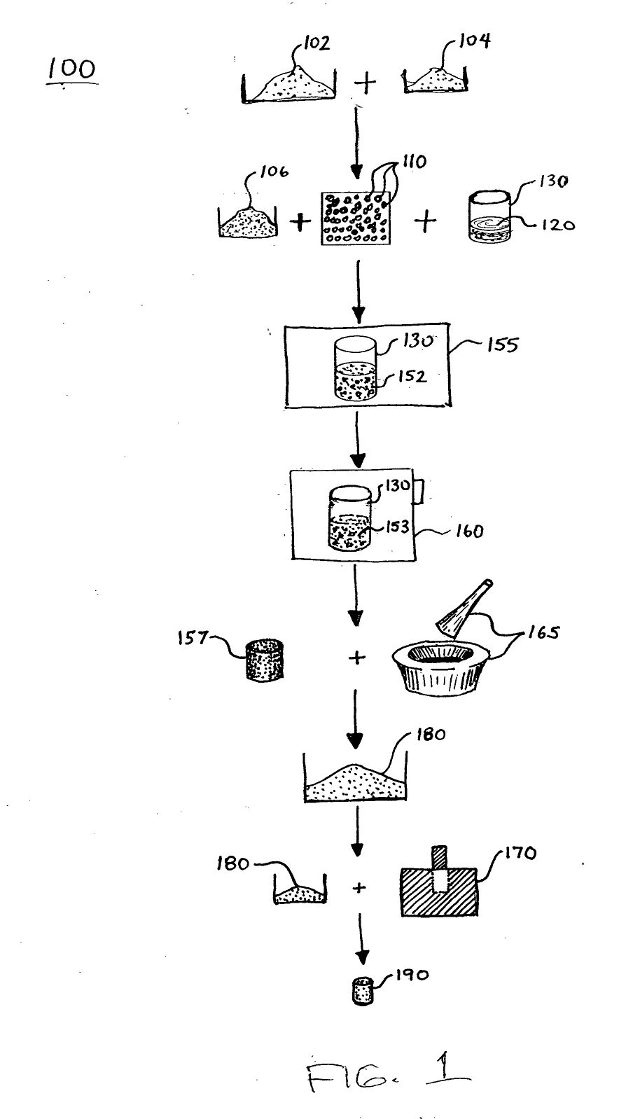

Turning to FIG. 1, a ball milling process 100 is shown by a schematic flowchart, which is one embodiment of the homogeneous mixing processes. The ball milling process 100 involves combining an organic powder host component 102 and an organic powder dopant component 104 to form an organic powder mixture 106. Depending upon the application and functionality of the organic mixture 106, the dopant component 104 may vary from 0.1 to 20% by weight of the total mixture weight. Organic powders used as a host component 102 in the present invention are Alq3, NPB and TBADN. Examples of some organic dopant components 104 used in this invention are DCJTP, Rubrene, OP31, DPQA and DBzR. The organic powder mixture 106 is placed in a container 130 and an emulsifying liquid 120 is provided to emulsify the organic materials producing a slurry of organic materials 152. Preferably the emulsifying liquid 120 is isopropyl alcohol or distilled water. The container 130 can be made of glass or high temperature metals such as Ta, W, or Pt. The ball milling process 100 is generally done wet by adding a liquid medium. Alternatively, mixing can be accomplished using a high-speed propeller, turbine blade or ultrasonication.

The organic powder mixture 106 is then mixed using a ball mill. Ceramic ball media 110 are added to the to the container 130, including the organic powder mixture 106 and the emulsifying liquid 120. The container 130 is sealed. The container 130 is placed inside a three-axis ball mill mixer 155 and allowed to mix for at least one hour until a homogeneous mixture of organic slurry 153 is obtained. The container 130 is removed from the ball mill mixer 155 and the ceramic ball media 110 are separated from the homogenous mixture of organic slurry 153.

The container 130 is placed inside a vacuum oven 160 and heated by a heater 154. During heating the homogeneous mixture of organic slurry 153 is mixed to assure that the homogeneity of the mixture is maintained. The homogeneous mixture of organic slurry 152 is heated until the emulsifying liquid 120 is evaporated and a homogeneous mixture of organic powder remains 180. After the emulsifying liquid 120 is evaporated, a solidified homogenous mixture of organic materials 157 is removed from the container. The solidified homogenous mixture of organic materials 157 is then pulverized to form a homogeneous mixture of organic powder 180, which can be used in the powder form or can be compacted. The solidified homogenous mixture of organic materials 157 can be pulverized using a mortar and pestle 165, ball mill, or any conventional pulverizing technique. The powder can be formed into a pellet a die press 170, ram press or any other conventional pellet-forming technique. The powder is compacted in a range of pressures between 3,000 and 20,000 pounds per square inch to form a pellet of a homogenous mixture of organic powder 190 for the purpose of physical vapor deposition on a substrate, which will form a part of an OLED display.

### WORKING EXAMPLE

### Example 1: The blue emission layer.

First, 2.0 grams of dopant component organic material TBP and 8.0 grams of host component organic material TBADN were combined in a glass beaker. Next, 50 to 80 cc of an organic fluid isopropyl alcohol were added to the organic materials to form an emulsion. Few ceramic balls ranging in 1/8 inch to 1/4 inch diameter were added to the emulsion which was transferred to an air-tight container. Next, the air-tight container was placed inside a 3-axis mixer for at least an hour and not exceeding four hours until all the organic components are thoroughly mixed. The mixed emulsion was then heated in a vacuum oven maintained between 10^{—1} and 10^{—3} Torr and temperatures between 50 and 80° C. in order to evaporate the fluid (isopropyl alcohol) from the emulsion.

The mixing and heating continued until the fluid was completely evaporated, leaving behind a homogeneous mixture of organic powder, which was compacted at a pressure of 5,000 pounds per square inch to form pellets for use in physical vapor deposition. The compacted pellet was placed in a quartz boat and the pellet was heated from the top using a Ta heater according to the prior art described by S. Van Slyke et al, SID 2002 Digest, pp. 886-889, 2002, which is incorporated herein for reference. Several OLED displays having the following structure were formed on a glass substrate coated with an indium-tin oxide anode:
Hole injection layer: CFx. Thickness=5 nm
HTL: NPB. Thickness=75 nm
EML: TBADN+2% TBP. Thickness=20 nm
ETL: Alq3. Thickness=35 nm
Cathode: MgAg. Thickness=200 mm

Initially, five OLED displays were made wherein the EML was formed by using a compacted pellet weighing approximately 2.0 grams and other organic layers such as a HTL and an ETL were formed using organic materials and a top heated quartz boat. Another set of five OLED displays was made after one hour of continuous evaporation. The compacted pellet was heated continuously for approximately 200 minutes until the pellet was completely consumed and a set of five OLED displays were made at intervals of 30 minutes.

A shutter during the continuous deposition process protected the substrates and the shutter was opened only when emission layers were deposited to form an OLED display. The average EL results of each set of five OLED displays are shown in Table 1. The OLED displays in group A denote the average performance of five OLED displays made at the beginning of the deposition process, OLED displays in group B denote the average performance of five displays made after 120 minutes of continuous deposition and OLED displays in group C denote the average EL performance of five OLED displays made after 180 minutes of deposition.

TABLE 1
EL results of blue OLED displays formed according to
the invention.

| Experi- | EML | OLED | Drive | Luminance | |
|---|---|---|---|---|---|
| ment | Composition | displays | Voltage | Yield (cd/A) | CIEx, y |
| 1 | TBADN + 2% | A | 7.1 V | 2.51 | 0.15, 0.20 |
| | TBP | | | | |
| 2 | TBADN + 2% | B | 7.0 V | 2.35 | 0.14, 0.19 |
| | TBP | | | | |
| 3 | TBADN + 2% | C | 6.8 | 2.40 | 0.14, 0.18 |
| | TBP | | | | |

The experimental results summarized in Table 1 indicate that the EL characteristics such as drive voltage, luminance yield and color coordinates, CIEx,y of the blue emission layer formed according to the invention remained uniform throughout the entire length of the deposition process indicating that the composition of the organic materials which included 98% TBADN (host) and 2% TBP (dopant) remained unchanged.

The invention has been described in detail with particular reference to certain preferred embodiments thereof, but it will be understood that variations and modifications can be effected within the spirit and scope of the invention.

### Parts List

| | |
|---|---|
| 100 | ball milling process |
| 102 | host component |
| 104 | dopant component |
| 106 | organic powder mixture |
| 110 | ceramic ball media |
| 120 | emulsifying liquid |
| 130 | container |
| 152 | slurry of organic material |
| 153 | homogenous mixture of organic slurry |
| 154 | heater |
| 155 | three-axis ball mill mixer |
| 157 | solidified homogeneous mixture of organic materials |
| 160 | vacuum oven |
| 165 | mortar and pestle |
| 170 | die press |
| 180 | homogenous mixture of organic powder |
| 190 | a pellet of a homogenous mixture of organic powder |

1. A method for forming homogeneous mixture of powders of organic materials including at least one dopant component and one host component to provide a homogeneous mixture for forming a pellet for thermal physical vapor deposition producing an organic layer on a substrate for use in an organic light-emitting device, comprising:
a) combining organic materials, such materials including at least one dopant component and one host component;
b) providing a liquid to emulsify the organic materials;
c) mixing the emulsified organic materials in a container to form a homogeneous mixture of organic material;
d) heating the organic materials in a container until the liquid is evaporated and a solidified homogeneous mixture of organic materials remain;
e) removing the solidified homogeneous mixture of organic materials from the container;
f) pulverizing the solidified mixture of organic materials into a homogeneous mixture of organic powder; and
g) compacting the homogenous mixture of organic powder, to form a pellet suitable for thermal physical vaporization to produce an organic layer on a substrate for use in an organic light-emitting device.

2. The method of claim 1 wherein the amount of dopant component varies between 0.1 and 20% by weight of the total weight of the mixture.

3. The method of claim 1 wherein the compaction of the homogeneous mixture of organic powder to form a pellet is compacted in a range of pressures between 3,000 and 20,000 pounds per square inch.

4. The method of claim 1 wherein the container is formed from glass or metal.

5. The method of claim 1, wherein the container includes high temperature metals Ta, W or Pt.

6. The method of claim 1, wherein the mixing includes using a ball mill, high-speed propeller, turbine blade or ultrasonication.

7. The method of claim 6, wherein the ultrasonication includes an ultrasonic horn, which operates in a range of frequencies between 10-30 kHz.
